(19) United States
(12) Patent Application Publication
(10) Pub. No.: US 2014/0177350 A1
(43) Pub. Date: Jun. 26, 2014

(54) SINGLE-ENDED SENSE AMPLIFIER CIRCUIT

(71) Applicant: EMEMORY TECHNOLOGY INC., Hsinchu (TW)

(72) Inventors: Yung-Jui Chen, New Taipei City (TW); Chen-Hao Po, Hsinchu City (TW); Chih-Hao Huang, Taichung City (TW)

(73) Assignee: EMEMORY TECHNOLOGY INC., Hsinchu (TW)

(21) Appl. No.: 13/726,179

(22) Filed: Dec. 23, 2012

(51) Int. Cl. G11C 7/06; G11C 7/12

(52) U.S. Cl. CPC G11C 7/065; G11C 7/12
USPC 365/189.05; 365/203

(57) ABSTRACT

A single-ended sense amplifier and a method for reading a memory cell are disclosed. The method includes the following steps. A bit line is charged according to a control signal. Thereafter, whether the dropoff time of the bit line voltage is greater or less than a predetermined time is deteremined. When the dropoff time of the voltage of the bit line is less than the predetermined time period, a first operation is sensed. On the other hand, when the dropoff time of the voltage of the bit line is greater than the predetermined time period, a second operation is sensed. The dropoff time of the voltage of the bit line is determined according to a parasitic capacitance on the bit line. A logic level of a sensing transistor circuit is retained and an output data signal according to the operation sensed is generated.

### BACKGROUND

1. Technical Field

The invention relates generally to a single-ended sense amplifier circuit, and more particularly, to a single-ended time-domain sense amplifier.

2. Related Art

With the advancement of technology, memory cells are continually shrinking in size, and as a consequence, the sensed voltage from the memory cell has been reduced. Although sense amplifier circuits are used in memory devices for sensing the logic levels of selected memory cells, the reduction in the memory cell size has meant unreliable performance for the operation of the sense amplifier.

To improve the reliability and speed of the sense amplifier under increasingly harsh conditions, sense amplifier designs have been developed towards decreasing the pre-charging time or eliminating the need of extra control signals. However, these designs may increase the area of the sense amplifier, employ a current mirror to compare a mirrored current with a reference current, or utilize diodes for the bit line charging. Accordingly, it is desirable to provide a single-ended time-domain sense amplifier for use in electronic devices.

### SUMMARY

Several exemplary embodiments accompanied with figures are described in detail below to further describe the invention in details.

The invention provides a single-ended sense amplifier circuit capable of time-domain sensing, including a pre-charge circuit, a sensing transistor circuit, and a latch circuit. The pre-charge circuit is coupled to a bit line to charge the bit line according to a control signal. The sensing transistor circuit is coupled to the bit line to read a memory cell. Moreover, the latch circuit is coupled to the sensing transistor circuit to retain a logic level of the sensing transistor circuit and to generate an output data signal acccording to an operation sensed. When a dropoff time of the voltage of the bit line is less than a predetermined time period, a first operation is sensed by the sensing transistor circuit. On the other hand, when the dropoff time of the voltage of the bit line is greater than the predetermined time period, a second operation is sensed by the sensing transistor circuit, and the dropoff time of the voltage of the bit line is determined according to a parasitic capacitance on the bit line.

The invention further provides a method for reading a memory cell, including the following steps. A bit line is charged according to a control signal. Thereafter, whether the dropoff time of the bit line voltage is greater or less than a predetermined time is deteremined. When the dropoff time of the voltage of the bit line is less than the predetermined time period, a first operation is sensed. On the other hand, when the dropoff time of the voltage of the bit line is greater than the predetermined time period, a second operation is sensed. The dropoff time of the voltage of the bit line is determined according to a parasitic capacitance on the bit line. The logic level of the sensing transistor circuit is retained and an output data signal according to the operation sensed is generated.

In summary, by determining whether the dropoff time of the voltage of the bit line corresponds to the read 0 or read 1 operation according to the discharge of the parasitic capacitance, the single-ended sense amplifiers and the methods for reading a memory cell embodied in the disclosure do not require current mirroring and comparison with a reference current. As a consequence, the single-ended sense amplifiers disclosed are low power and occupy a small area.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1 is a schematic block diagram of a single-ended sense amplifier according to an embodiment of the invention.

FIG. 2 is a circuit diagram of a plurality single-ended sense amplifiers in a memory array according to an embodiment of the invention.

FIG. 3 is a timing diagram of the signals in a single-ended sense amplifier depicted in FIG. 2.

FIG. 4 is a flow diagram of a method for reading a memory cell according to an embodiment of the invention.

FIG. 5 is a flow diagram of a method for reading a memory cell according to another embodiment of the invention.

### DETAILED DESCRIPTION OF DISCLOSED EMBODIMENTS

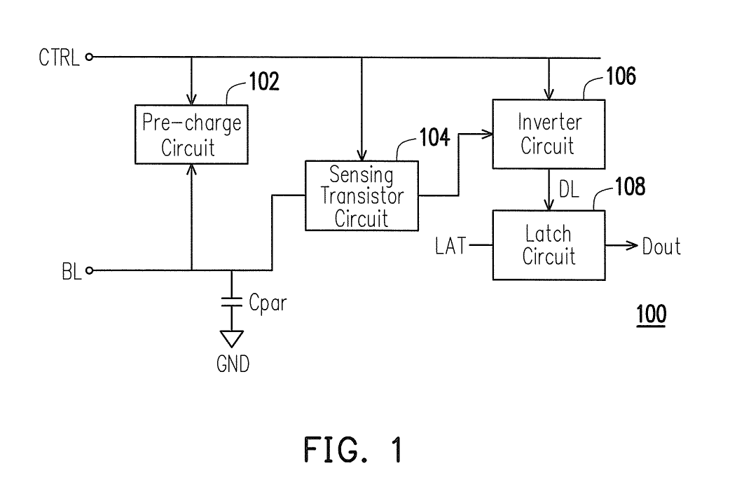

FIG. 1 is a schematic block diagram of a single-ended sense amplifier according to an embodiment of the invention. With reference to FIG. 1, a single-ended sense amplifier 100 includes a pre-charge circuit 102, a sensing transistor circuit 104, an inverter circuit 106, and a latch circuit 108. The pre-charge circuit 102 is coupled to a bit line BL to charge the bit line BL according to a control signal CTRL. The sensing transistor circuit 104 is coupled to the bit line BL to read a memory cell (not drawn). The inverter circuit 106 is coupled between the sensing transistor circuit 104 and the latch circuit 108. The latch circuit 108 is coupled to the sensing transistor circuit 104 to retain a logic level of the sensing transistor circuit 104 and to generate an output data signal DOUT acccording to a sensed read signal DL.

In the present embodiment, the single-ended sense amplifier 100 may be a circuit block in a memory such as a static random-access memory (SRAM), for example. However, the invention is not limited thereto, and the single-ended sense amplifiers embodied in the disclosure may be part of other types of memories where time-domain sensing is needed.

As shown in FIG. 1, a parasitic capacitance Cpar exists on the bit line BL, which is connected to ground GND. The discharge of the parasitic capacitance Cpar on the bit line BL determines the dropoff time of the voltage of the bit line. In the present embodiment, when a dropoff time of the voltage of the bit line BL is less than a predetermined time period, a read 0 operation is sensed by the sensing transistor circuit 104. On the other hand, when the dropoff time of the voltage of the bit line BL is greater than the predetermined time period, a read 1 operation is sensed by the sensing transistor circuit 104. However, the sensing mechanism of the single-ended sense amplifier 100 is not limited to the afore-described embodiment. In some embodiments of the invention, a read 1 operation can be sensed by the sensing transistor circuit 104 when the dropoff time of the voltage of the bit line BL is less than a predetermined time period. Moreover, a read 0 operation can be sensed by the sensing transistor circuit 104 when the dropoff time of the voltage of the bit line BL is greater than the predetermined time period.

Accordingly, by determining whether the dropoff time of the voltage of the bit line corresponds to the read 0 or read 1 operation according to the discharge of the parasitic capacitance, the single-ended sense amplifiers embodied in the disclosure do not require current mirroring and comparison with a reference current. As a consequence, the single-ended sense amplifiers disclosed are low power and occupy a small area.

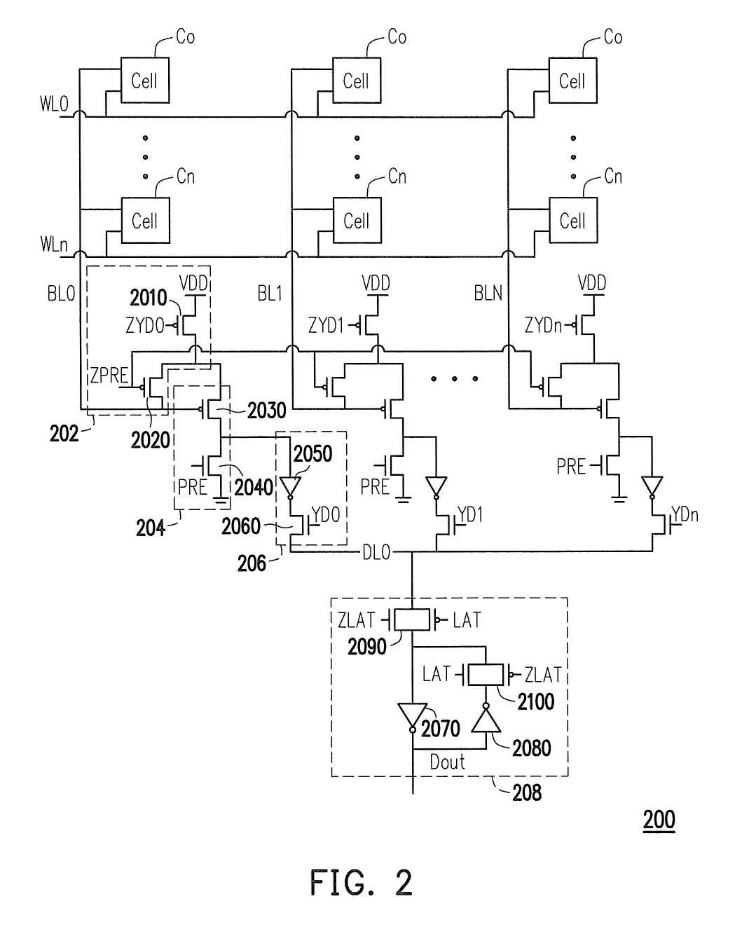

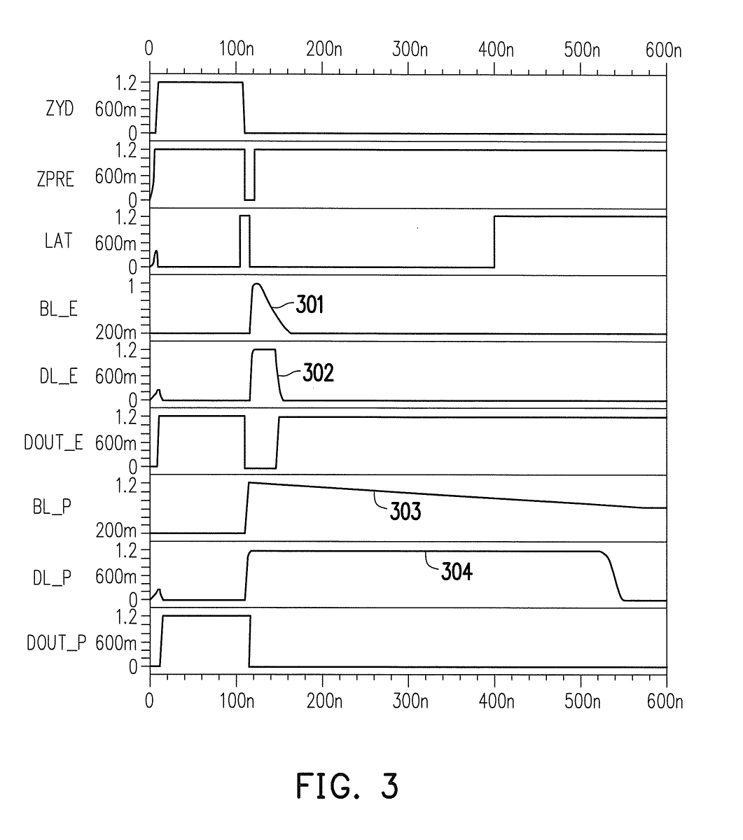

To further describe the single single-ended sense amplifier 100 depicted in FIG. 1, a circuit diagram of a plurality single-ended sense amplifiers in a memory array are shown in FIG. 2. Moreover, a timing diagram of the signals in a single-ended sense amplifier in FIG. 2 is shown in FIG. 3. With reference to FIGS. 2 and 3, in the memory array 200, each of the memory cells C0-Cn is coupled to a corresponding word line WL0-WLn and a bit line BL0-BLn. For clarity of description, the circuit operation of the memory array 200 will be described for the read operation of the bit line BL0 by a single-ended sense amplifier formed by a pre-charge circuit 202, a sensing transistor circuit 204, an inverter circuit 206, and a latch circuit 208.

Initially, the control signals ZYD0 and ZPRE are at logic high levels, and the bit line BL0 is at logic low level. The control signals ZYD0 and ZPRE then change to logic low levels, thereby charging the bit line BL0 through the active PMOS transistors 2010 and 2020. In the case of sensing a read 0 operation, when a dropoff time of the voltage the bit line BL0 is less than a predetermined time period tau, a read 0 operation is sensed by the sensing transistor circuit 204 and outputted to the inverter circuit 206. In FIG. 3, the predetermined time period tau is taken to be 100 ns as an example, and the waveforms 301 and 302 of the signals BL_E from the bit line BL0 and a sensed read signal DL_E from the data line DL0 clearly show that the dropoff time of the voltage on the bit line is less than the predetermined time period tau.

On the other hand, in the case of sensing a read 1 operation, when the dropoff time of the voltage of the bit line BL0 is greater than the predetermined time period tau, a read 1 operation is sensed by the sensing transistor circuit 204 and outputted to the inverter circuit 206. In FIG. 3, since the predetemined time period tau is taken to be 100 ns as an example, the waveforms 303 and 304 of the signals BL_P from the bit line BL0 and a sensed read signal DL_P from the data line DL0 clearly show that the dropoff time of the parasitic capacitance Cpar on the bit line BL0 is greater than the predetermined time period tau. In the present embodiment, since a parasitic capacitance Cpar exists on the bit line BL0, which is connected to ground GND, the discharge of the parasitic capacitance Cpar on the bit line BL0 determines the dropoff time of the voltage of the bit line BL0. Moreover, it should be appreciated that according to an embodiment of the invention, the predetermined time period tau can be between the dropoff time of the read 0 operation (e.g. an erase operation) and the dropoff time of the read 1 operation (e.g. a program operation) sensed by the sensing transistor circuit 204.

Furthermore, it should be noted that the sensing transistor circuit 204 may also be configured to sense a read 0 operation when the dropoff time of the voltage of the bit line BL0 is greater than the predetermined time period tau. In addition, the sensing transistor circuit 204 may be configured to sense a read 1 operation when the dropoff time of the voltage of the bit line BL0 is less than the predetermined time period tau.

In the present embodiment, the latch circuit 208 is coupled to the sensing transistor circuit 204 to retain a logic level of the bit line BL0 and to generate an output data signal acccording to the sensed read signal. When the read 0 operation is sensed by the sensing transistor circuit 204, the low voltage level of the bit line BL0 is retained by the latch circuit 208, as shown by the output data signal DOUT_E. In the case of the read 1 operation being sensed by the sensing transistor circuit 204, the high logic level of the bit line BL0 is retained by the latch circuit 208.

In some embodiments of the invention, the latch circuit 208 may include two inverters 2070 and 2080 cross coupled with each other. Moreover, the latch circuit 208 may further include two MOS transistors 2090 and 2100 coupled to the two inverters 2070 and 2080 cross coupled with each other. Furthermore, the sensing transistor circuit 204 may include a PMOS transistor 2030 coupled to a NMOS transistor 2040, in which the NMOS transistor 2040 is substantially weak compared to the PMOS transistor 2030. The PMOS transistor 2030 may serve as a sensing transistor, and the NMOS transistor 2040 may serve as a reset transistor, for example Moreover, the inverter circuit 206 coupled between the sensing transistor circuit 204 and the latch circuit 208 may include an inverter 2050 and a NMOS transistor 2060 coupled in series. In an alternative configuration according to some embodiments of the invention, the sensing transistor circuit 204 may be configured such that the PMOS transistor 2030 is substantially weak compared to the NMOS transistor 2040, in which the NMOS transistor 2040 serves as a sensing transistor, and the PMOS transistor 2030 serves as a reset transistor.

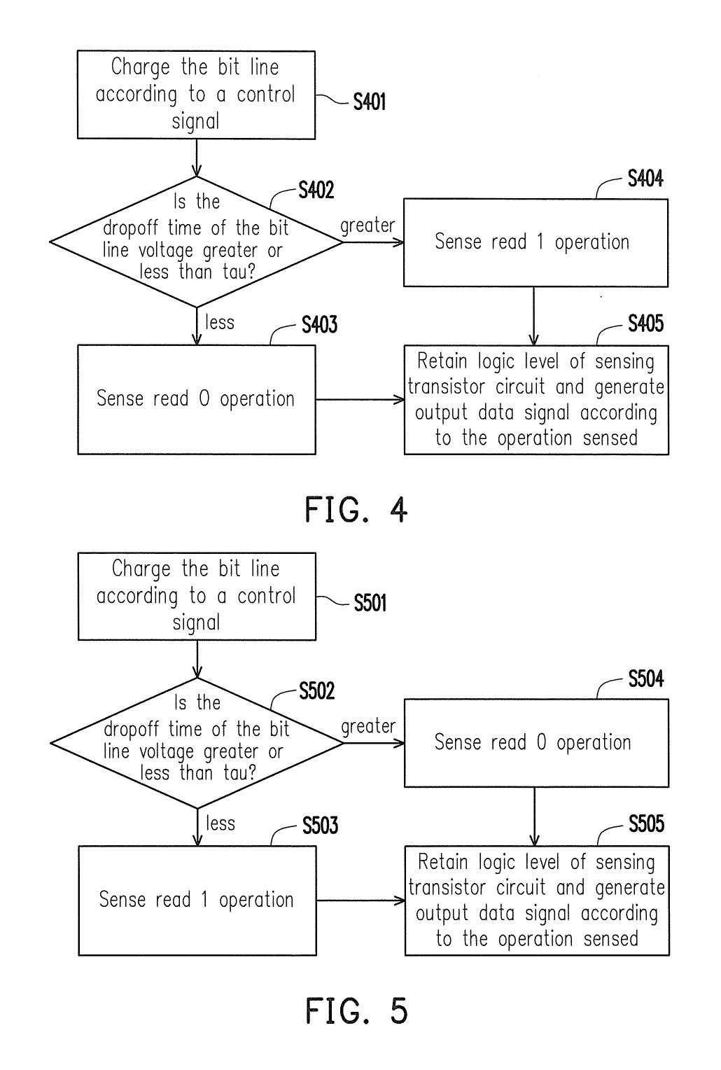

From another perspective, a method for reading a memory cell can be obtained. FIG. 4 is a flow diagram of a method for reading a memory cell according to an embodiment of the invention. In Step S401, a bit line is charged according to a control signal. Thereafter, whether the dropoff time of the bit line voltage is greater or less than a predetermined time is deteremined in Step S402. When the dropoff time of the voltage of the bit line is less than the predetermined time period, a read 0 operation is sensed (Step S403). On the other hand, when the dropoff time of the voltage of the bit line is greater than the predetermined time period, a read 1 operation is sensed (Step S404). In the present embodiment, the dropoff time of the voltage of the bit line is determined according to a parasitic capacitance on the bit line. Moreover, the logic level of the sensing transistor circuit is retained and an output data signal according to the operation sensed is generated (Step S405).

In some embodiments of the invention, the method for reading the memory cell shown in FIG. 4 may be adjusted. FIG. 5 is a flow diagram of a method for reading a memory cell according to another embodiment of the invention. In Step S501, a bit line is charged according to a control signal. Thereafter, whether the dropoff time of the bit line voltage is greater or less than a predetermined time is deteremined in Step S502. When the dropoff time of the voltage of the bit line is less than the predetermined time period, a read 1 operation is sensed (Step S503). On the other hand, when the dropoff time of the voltage of the bit line is greater than the predetermined time period, a read 0 operation is sensed (Step S504). In the present embodiment, the dropoff time of the voltage of the bit line is determined according to a parasitic capacitance on the bit line. Moreover, the logic level of the sensing transistor circuit is retained and an output data signal according to the operation sensed is generated (Step S505).

In view of the foregoing, by determining whether the dropoff time of the voltage of the bit line corresponds to the read 0 or read 1 operation according to the discharge of the parasitic capacitance, the single-ended sense amplifiers and the methods for reading a memory cell embodied in the disclosure do not require current mirroring and comparison with a reference current. As a consequence, the single-ended sense amplifiers disclosed are low power and occupy a small area.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A single-ended sense amplifier circuit, comprising:
a pre-charge circuit coupled to a bit line to charge the bit line according to a control signal;
a sensing transistor circuit coupled to the bit line to read a memory cell; and
a latch circuit coupled to the sensing transistor circuit to retain a logic level of the sensing transistor circuit and to generate an output data signal acccording to an operation sensed,
wherein when a dropoff time of a voltage of the bit line is less than a predetermined time period, a first operation is sensed by the sensing transistor circuit, and when the dropoff time of the voltage of the bit line is greater than the predetermined time period, a second operation is sensed by the sensing transistor circuit, and the dropoff time of the voltage of the bit line is determined according to a parasitic capacitance on the bit line.

2. The single-ended sense amplifier circuit of claim 1, wherein the predetermined time period is between the dropoff time of the first operation and the dropoff time of the second operation sensed by the sensing transistor circuit.

3. The single-ended sense amplifier circuit of claim 1, wherein the first operation is a read 0 operation, and the second operation is a read 1 operation.

4. The single-ended sense amplifier circuit of claim 1, wherein the first operation is a read 1 operation, and the second operation is a read 0 operation.

5. The single-ended sense amplifier circuit of claim 1, wherein the latch circuit comprises:
two inverters cross coupled with each other.

6. The single-ended sense amplifier circuit of claim 1, wherein the latch circuit further comprises:
two metal oxide semiconductor (MOS) transistors coupled to the two inverters cross coupled with each other.

7. The single-ended sense amplifier circuit of claim 1, wherein the sensing transistor circuit comprises:
a p-channel metal oxide semiconductor (PMOS) transistor coupled to a n-channel metal oxide semiconductor (NMOS) transistor, wherein the NMOS transistor is substantially weak compared to the PMOS transistor.

8. The single-ended sense amplifier circuit of claim 1, wherein the sensing transistor circuit comprises:
a NMOS transistor coupled to a PMOS transistor, wherein the PMOS transistor is substantially weak compared to the NMOS transistor.

9. The single-ended sense amplifier circuit of claim 1, further comprising:
an inverter circuit coupled between the sensing transistor circuit and the latch circuit.

10. A method for reading a memory cell, comprising:
charging a bit line according to a control signal;
when a dropoff time of the voltage of the bit line is less than a predetermined time period, sensing a first operation; and
when the dropoff time of the voltage of the bit line is greater than the predetermined time period, sensing a second operation,
wherein the dropoff time of the voltage of the bit line is determined according to a parasitic capacitance on the bit line.

11. The method of claim 10, wherein the predetermined time period is between the dropoff time of the first operation and the dropoff time of the second operation sensed by the sensing transistor circuit.

12. The method of claim 10, further comprising:
retaining a logic level of a sensing transistor circuit and generating an output data signal according to the operation sensed.

13. The method of claim 10, wherein the first operation is a read 0 operation, and the second operation is a read 1 operation.

14. The method of claim 10, wherein the first operation is a read 1 operation, and the second operation is a read 0 operation.
